(19) United States
(12) Patent Application Publication
(10) Pub. No.: US 2026/0360418 A1
(43) Pub. Date: Nov. 12, 2026

(54) CAPACITIVE NOISE COMPENSATION FOR A READ BITLINE IN A MACHINE MEMORY

(71) Applicant: NVIDIA Corp., Santa Clara, CA (US)

(72) Inventors: Lalit Gupta, FREMONT, CA (US); Jesse San-Jey Wang, Santa Clara, CA (US)

(73) Assignee: NVIDIA Corp., Santa Clara, CA (US)

(21) Appl. No.: 19/376,767

(22) Filed: Oct. 31, 2025

Related U.S. Application Data
(62) Division of application No. 18/540,314, filed on Dec. 14, 2023.

(51) Int. Cl. G11C 11/413; G11C 5/06; G11C 5/10; G11C 7/02; G11C 7/06; G11C 7/12; G11C 11/419

(52) U.S. Cl. CPC G11C 11/413; G11C 5/063; G11C 5/10; G11C 7/02; G11C 7/06; G11C 7/12; G11C 11/419

(57) ABSTRACT

Memory systems including bit-storing cells coupled to a read bitline, a keeper circuit configured to activate during a read operation on the bit-storing cells, a read latch coupled to the read bitline, and a capacitive coupling between an output of the read latch and a node on the read bitline disposed between the keeper circuit and the bit-storing cells. A capacitance of the capacitive coupling is configured to cancel noise generated by a Miller capacitor of the read latch.

### CROSS REFERENCE TO RELATED APPLICATIONS

This application claims priority and benefit as a divisional of U.S. application Ser. No. 18/540,314, “Capacitive Noise Compensation for a Read Bitline in a Machine Memory”, filed on Dec. 14, 2023, the contents of which are incorporated herein by reference in their entirety.

### BACKGROUND

A memory bank is a unit of data storage in electronics, which is hardware-dependent. In a computer, for example, the memory bank may be determined by the physical organization of the hardware memory. In a typical static random-access memory (static RAM or SRAM), a bank may include multiple rows and columns of storage units, and is usually spread out across circuits. An SRAM is a type of semiconductor memory that uses bi-stable latching circuitry (e.g., a flip-flop or a portion thereof) to store each bit. In a single read or write operation, generally only one bank is accessed. Certain types of memory may implement a register file.

A common feature of most modern memories is the use of a hierarchical bitline arrangement in which, instead of a single bitline that runs the complete height of a column of memory cells and connects to each cell in the column, a multi-level structure is used. Effectively, a single bitline is broken up into multiple “local bitlines”, each of which connects to the memory cells in a part of the column. A “global bitline” also runs the height of the column, and is connected to the local bitlines via switches. The memory read and write circuits connect to the global bitline, and not directly interface to the local bitline. During a memory access, only a local bitline in the relevant part of the column are connected (via a local-to-global switch) to the global bitline.

Bit cell-based register files are often organized in multiple array banks. Each bank may be organized with multiple bit-cells on a local bitline, wherein the bitline is local to the bank. The bitline conveys information when a memory access (e.g., read, write) occurs.

The bitline may utilize a keeper or pull-up device which serves the purpose of retaining the state of the bitline when it is not actively driven. A separate precharge device pulls the bitline “high” or up after the evaluation phase of the memory access completes.

The keeper device is required to work across a wide range of process, voltage and temperature (PVT) variations, and prevent the bitline from leaking current and transitioning to “low” when it is not desired. In another example, a contention may exist between the keeper device (pulling the bitline “high”) and a bank's bitline pull-down device (pulling the bitline “low”).

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a memory controller in accordance with one embodiment.

FIG. 2 depicts a timing diagram in accordance with one embodiment.

FIG. 3 depicts read-out logic for a bit-storing cell in one embodiment.

FIG. 4 depicts an example of a bit-storing cell and associated logic to read the values stored in the cells out to a read bitline.

FIG. 5 depicts an example of logic to read the values stored in the cells out to a read bitline with Miller capacitor noise compensation.

FIG. 6 depicts another example of logic to read the values stored in the cells out to a read bitline with Miller capacitor noise compensation.

FIG. 7 depicts an example of a memory system utilizing bit lines traversing multiple memory banks.

FIG. 8 depicts applications of a memory system utilizing the disclosed mechanisms in accordance with one embodiment.

### DETAILED DESCRIPTION

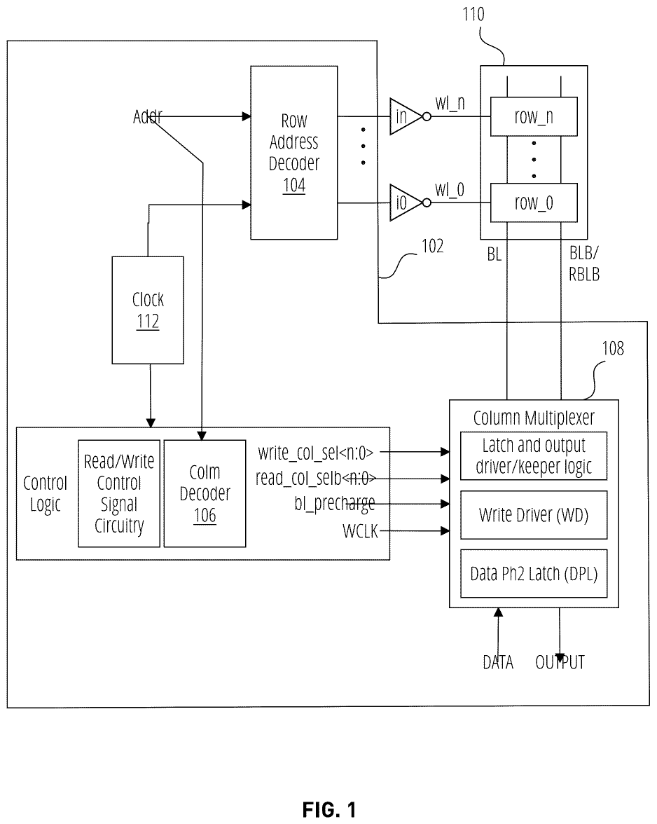

FIG. 1 depicts a memory controller 102 in one embodiment. A row address decoder 104 translates a memory address into a row (word line) selection, and a column decoder 106 translates the address into column (bitline) selection(s). The bit-storing cells along the selected row and column are read by the column multiplexer 108, which includes latches for data read from the machine memory 110, keeper logic (described below), and logic for writing values into the bit-storing cells of the machine memory 110. These operations may be performed synchronously and thus coordinated by a clock 112.

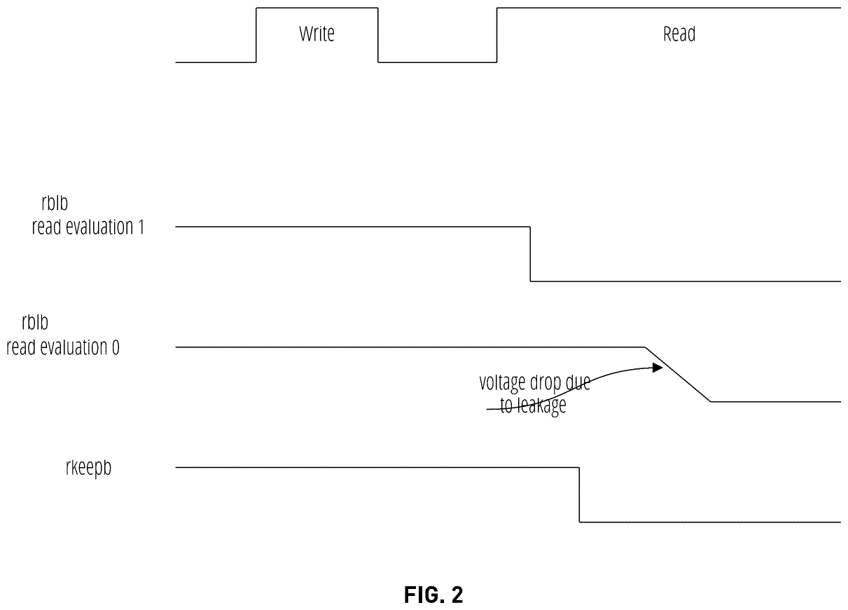

FIG. 2 depicts a timing diagram for read evaluation 1 and read evaluation 0 with respect to a keeper signal for a bitline (rblb). For read evaluation 1, the keeper signal is triggered soon after the discharge of rblb, so as not to interfere with the discharge and create an erroneous reading. During read evaluation 0 rblb should ideally remain charged to VDD but due to leakage it may discharge to the point that an erroneous “1” value is detected in the evaluated cell. If the keeper signal is not triggered, rblb will start to discharge due to leakage (as depicted), which may, depending on latencies in the system, lead to erroneous readings. Hence the timing of the keeper signal may be critical. Because leakage and other factors may vary over large circuit areas due to process, timing, and voltage variations, among other things, the timing of the keeper signal becomes highly constrained.

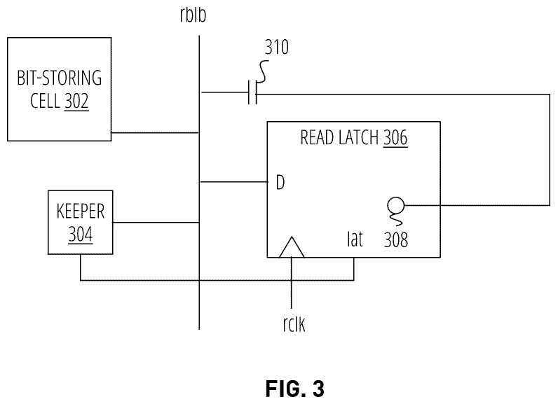

FIG. 3 depicts read-out logic for a bit-storing cell 302 in one embodiment. The read-out logic comprises a keeper circuit 304, a read latch 306 with an internal inverting node 308, and a capacitor 310. For simplicity of description, other logic that may be utilized in various embodiments for read-out of values from the bit-storing cell 302 is not depicted. During a read evaluation, the keeper circuit 304 may be activated to maintain a floating voltage level on rblb to meet the setup and hold time of the read latch 306. To mitigate the effects of parasitic noise a coupling through the capacitor 310 is made from the internal inverting node 308 of the read latch 306 to rblb.

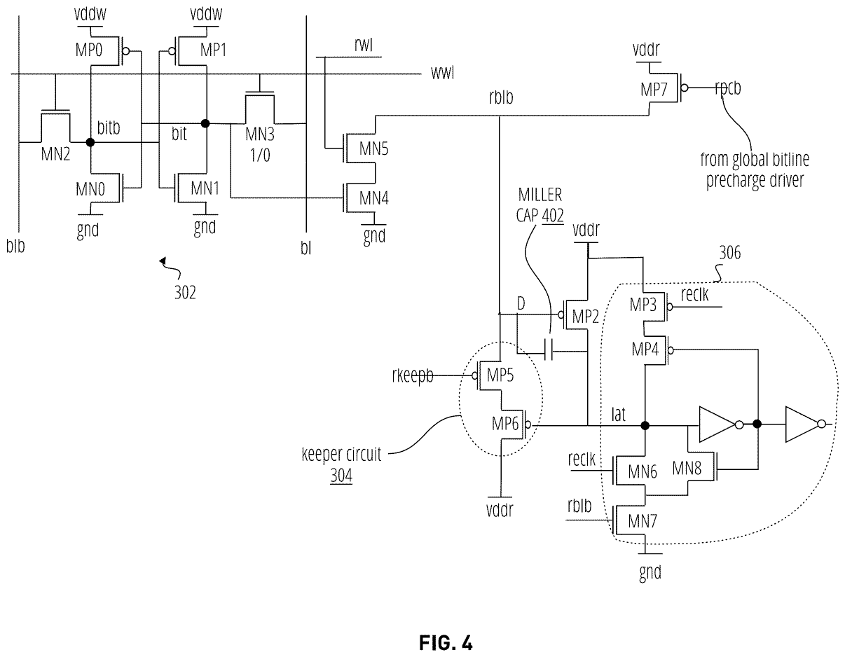

FIG. 4 depicts an example of a bit-storing cell and associated logic to read the values stored in the cells out to a read bitline (rblb). The bit-storing cell comprises NMOS transistors MN0-MN5 and PMOS transistors MP0 and MP1. A bit value bit and its complement bitb are stored in the bit-storing cell, the core of which comprises header transistors MP0 and MP1, and footer transistors MN0 and MN1. The writing of bits into the bit-storing cell from the bit lines bl and blb is controlled by the write word line (WWL) and access transistors MN2 and MN3. The read word line (RWL) and access transistors MN4 and MN5 control the reading of the stored bit to the read bitline rblb, which is pre-charged for the read via PMOS transistor MP7.

The bit-storing cell depicted in this example operates in a supply voltage domain vddw, and the read logic for the bit-storing cell, including the read latch 306, operates in a supply voltage domain vddr. Depending on the implementation, these two supply voltages may be the same, or different.

The read bitline rblb is coupled to a keeper circuit 304. The keeper circuit 304 comprises PMOS transistors MP5 and MP6. The read bitline rblb is further coupled to an output read latch 306 via PMOS transistor MP2. Signal rpcb is applied to precharge rblb and the keeper signal rkeepb maintains the precharge long enough for the bit value on rblb to settle at node lat (i.e., the setup and hold time) for capture by the read latch 306 upon receipt of the read clock reclk. In this example the read latch 306 comprises NMOS transistors MN6-MN8 and PMOS transistors MP3 and MP4.

A Miller capacitor, also known as a Miller capacitance, refers to a specific type of capacitor formed between the terminals of a transistor. The Miller capacitor introduces a feedback path that affects the gain and frequency response of the transistor. The Miller capacitance phenomenon arises due to the internal capacitance present in semiconductor transistors. This internal capacitance may have a significant undesirable impact on the overall circuit performance, i.e., it may be ‘parasitic’.

A parasitic Miller capacitor 402 may form between rblb and the lat node, and by way of capacitive coupling between rblb and lat, generates noise during a read operation. This noise may be particularly impactful when rblb is floating in a high-voltage state (meaning, it is precharged), and may result in the capture of a wrong bit value by the read latch. The impact of the Miller capacitor 402 may also be inversely proportional to the number of rows of bitcells serviced by rblb in the memory bank. In other words, the Miller capacitor 402 may decrease the signal to noise ratio at the lat node to a greater extent as the number of memory rows decreases. The impact of the Miller capacitor 402 may therefor be especially high in memory systems with relatively fewer memory rows, such as register files.

Conventionally, mitigating the negative effects of the Miller capacitor 402 has proven quite challenging, due to the multivariate problem of simultaneously balancing impact on power consumption (e.g., leakage and/or idle power drain), circuit area, read bandwidth (e.g., clock-to-Q), and noise.

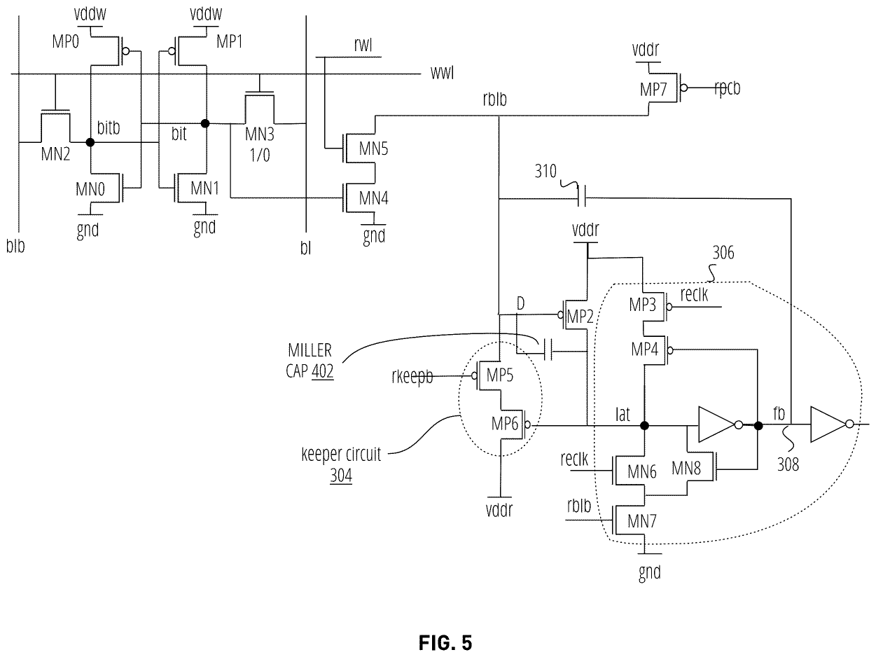

Counterintuitively, noise resulting from the parasitic Miller capacitor 402 may in one embodiment be mitigated to a large extent by introduction of yet more capacitive noise into the system, such as by way of a capacitor 310 coupled between the read bit line rblb and an (e.g., internal) inverting node fb of the read latch 306. An example of such a configuration is depicted in FIG. 5. As is known in the art, an “internal” node is a node that is not a external connection point (a ‘terminal’) in a standard cell layout of a logic cell.

The feedback capacitive effects introduced by the coupling of capacitor 310 between rblb and the output of the read latch 306 only come into play due to a high →low transition of the lat node. If the bit value read out of the bit-storing cell in the previous read cycle was low (e.g., logic “0”), negligible coupling effects backward between rblb and the output of the read latch 306. One benefit thereby arising is that leakage current and hence power consumption are not significantly impacted in states where the effects of the Miller capacitor 402 are less impactful on generating noise at the lat node, e.g., in states other than a transition of rblb from high to low voltage levels. The extended timing window for latching the read bit value arising from application of the keeper signal rkeepb to the read bit line rblb is maintained.

The disclosed mechanism is responsive to Miller capacitor 402 noise due to the very low hysteresis of the feedback signal loop through the capacitor 310 (a single inverter delay). Thus, the disclosed mechanisms may address multiple constraints on timing, power consumption, and noise reduction with implementation-negligible layout and routing costs.

Configurations in accordance with this embodiment may achieve a substantial noise reduction (e.g., a 9× improvement in signal-to-noise ratio in some cases) at the lat node input to the read output read latch 306. Negative impact on read bandwidth (e.g., due to increases in clock-to-Q of the read latch 306) may be acceptable in implementations such as register files where the number of memory rows is relatively small and clock-to-Q delay is not a substantial factor in the critical timing paths.

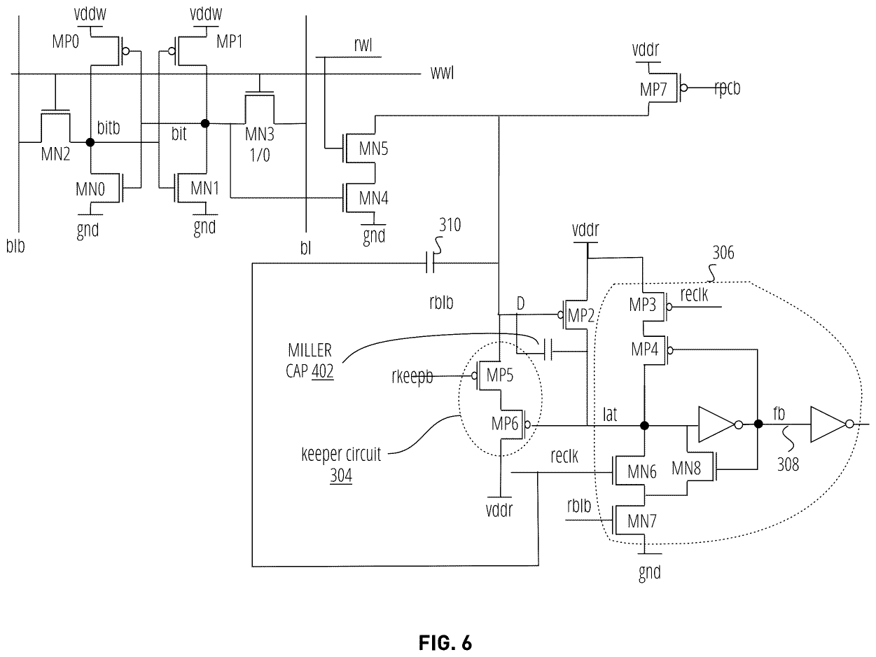

FIG. 6 depicts an alternative embodiment in which the noise signal fed back to the read bit line rblb is sourced from the read clock signal rclk that drives the read latch 306. A drawback of this implementation over the one depicted in FIG. 5 is that noise from the read clock rclk is generated on rblb even in states where the Miller capacitor 402 does not generate operationally-impactful noise at node lat.

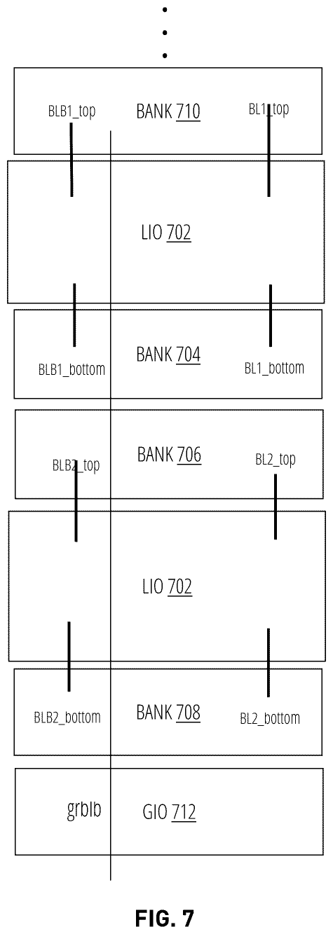

FIG. 7 depicts an example of a multi-bank memory system utilizing a plurality of local IO drivers 702 and local bit lines. The depicted example comprises memory banks 704, 706, 708, 710, but there may be more or fewer than this, depending on the implementation. In this example, each local IO driver 702 drives a bit line that is local to (does not extend beyond) a pair of the memory banks.

The local IO drivers 702 share common IO logic 712 (i.e., GIO). In some memory technologies, a local bit line may extend through more than two memory banks, but generally less than all of the memory banks in the memory. In some embodiments, such as where the memory system is a register file, a global read bit line grblb may extend from the memory controller (e.g., column multiplexer 108) to traverse the memory banks. Depending on the implementation, a keeper circuit may be configured on each local read bitline, or a keeper circuit may be configured on the global read bitline.

In one embodiment the capacitor 310 is configured within the common IO logic 712 and utilizes circuit area conventionally allocated to dummy circuits (circuits without functional contribution to the memory system) therein. In another embodiment the capacitors 310 are configured within the local IO drivers 702 and utilizing circuit area conventionally allocated to dummy circuits therein.

The capacitor 310 may be implemented as a metal cap, MOS cap, or in other manners well understood in the art. In one particular embodiment, the capacitor 310 is implemented as a parasitic Miller capacitor (e.g., between gate and drain of a MOS device) that mirrors the capacitance of the Miller capacitor 402 to compensate, or a fraction (e.g., between 30% and 90% of the capacitance) of the Miller capacitor 402 to compensate. For example, a single finger of poly material may be utilized to implement the capacitor 310 in some embodiments, which may comprise substantially less capacitance than the Miller capacitor 402.

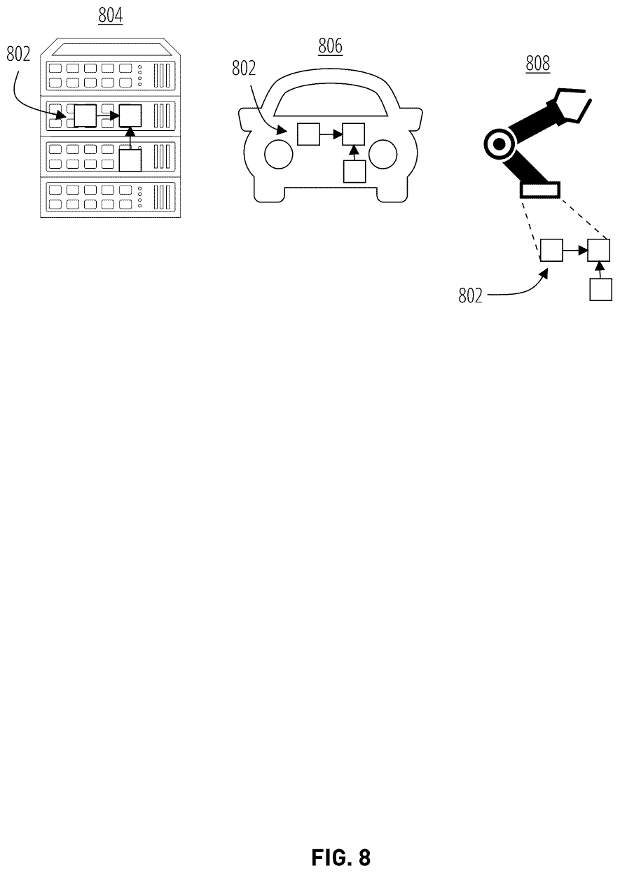

FIG. 8 depicts exemplary scenarios for use of a memory system 802 utilizing the disclosed mechanisms. A memory system 802 may be utilized in a computing system 804 (e.g., a server/data center system), a vehicle 806, and a robot 808, to name just a few examples. The memory system 802 may comprise a plurality of memory banks, a memory controller, and local IO drivers for the memory banks in accordance with the embodiments described herein, for example.

### LISTING OF DRAWING ELEMENTS

102 memory controller
104 row address decoder
106 column decoder
108 column multiplexer
110 machine memory
112 clock
302 bit-storing cell
304 keeper circuit
306 read latch
308 internal inverting node
310 capacitor
402 Miller capacitor
702 local IO driver
704 bank
706 bank
708 bank
710 bank
712 common IO logic
802 memory system
804 computing system
806 vehicle
808 robot

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S. C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A memory system comprising:
a memory bank comprising a plurality of bit-storing cells;
the bit-storing cells coupled to a read bitline;
a keeper circuit configured to activate during a read operation on the bit-storing cells;
a read latch coupled to the read bitline; and
a capacitor coupled between an output of the read latch and a node disposed on the read bitline between the keeper circuit and the bit-storing cells.

2. The memory system of claim 1, wherein the capacitor forms a connection between an inverting node of the read latch and the read bitline.

3. The memory system of claim 2, wherein the inverting node comprises an internal node of the read latch.

4. The memory system of claim 1, wherein a capacitance of the capacitor is configured to cancel noise generated by a Miller capacitor of the read latch.

5. The memory system of claim 1, wherein the capacitor is formed in a local input/output (IO) driver for a plurality of memory banks of the memory system.

6. The memory system of claim 5, wherein the the capacitor is formed from a single finger of poly.

7. The memory system of claim 1, wherein the capacitor is formed in a global input/output (IO) driver of the memory system.

8. The memory system of claim 1, wherein a capacitance of the capacitor and a keeper circuit timing are cooperatively configured to maintain a bit value from the read bitline at an input of the read latch to satisfy a setup and hold time of the read latch.

9. A circuit comprising:
a bit-storing cell;
a read latch coupled to the bit-storing cell via a read bitline; and
a capacitive feedback loop between a clock input of the read latch and the read bitline.

10. The circuit of claim 9, wherein a capacitance of the capacitive feedback loop is configured to cancel noise generated by a Miller capacitor of the read latch.

11. The circuit of claim 9, wherein the capacitive feedback loop and timing of a keeper circuit for the read bitline are cooperatively configured to maintain a bit value from the read bitline at an input of the read latch to satisfy a setup and hold time of the read latch.

12. A memory system comprising:
a plurality of bit-storing cells coupled to a read bitline;
a keeper circuit configured to activate during a read operation on the bit-storing cells;
a read latch coupled to the read bitline;
a capacitive coupling between (a) an output of the read latch, and (b) a node on the read bitline disposed between the keeper circuit and the bit-storing cells, wherein a capacitance of the capacitive coupling is configured to cancel noise generated by a Miller capacitor of the read latch.

13. The memory system of claim 12, wherein the capacitive coupling connects an inverting node of the read latch to the read bitline.

14. The memory system of claim 13, wherein the inverting node comprises an internal node of the read latch.

15. The memory system of claim 12, wherein the capacitance is generated in a local input/output (IO) driver for a plurality of memory banks of the memory system.

16. The memory system of claim 15, wherein the the capacitance is generated from a single finger of poly.

17. The memory system of claim 12, wherein the capacitance is generated in a global input/output (IO) driver of the memory system.

18. The memory system of claim 12, wherein the capacitance and a keeper circuit timing are cooperatively configured to maintain a bit value from the read bitline at an input of the read latch to satisfy a setup and hold time of the read latch.
